(19) United States
(12) Patent Application Publication
(10) Pub. No.: US 2025/0379088 A1
(43) Pub. Date: Dec. 11, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP)

(21) Appl. No.: 19/229,134

(22) Filed: Jun. 5, 2025

(30) Foreign Application Priority Data
Jun. 10, 2024 (JP) 2024-093455

(51) Int. Cl. H01L 21/683; H01J 37/32

(52) U.S. Cl. CPC H01L 21/6833; H01J 2237/2007; H01J 37/32715

(57) ABSTRACT

The electrostatic chuck 10 includes: a first portion 101 including a surface 110 on which a wafer W is placed; and a second portion 102 projecting from an outer peripheral end of the first portion 101 further toward an outer peripheral side, and including a surface 180 on which an annular member RE is placed. On a part of the surface 180, a roughened surface part 182 is provided to enable surrounding gas to easily enter a space between itself and the annular member RE as compared with another portion of the surface 180.

### CROSS-REFERENCE TO RELATED APPLICATION

This application is based upon and claims the benefit of priority from Japanese Patent Application No. 2024-093455 filed on June 10, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to adsorb and hold a wafer such as a silicon wafer to be processed. The electrostatic chuck includes a dielectric substrate provided with an adsorption electrode. When a voltage is applied to the adsorption electrode, an electrostatic force is generated, and the wafer placed on the dielectric substrate is adsorbed and held.

During a process on the wafer, an annular member, which is called a focus ring and the like, is arranged around the wafer. For example, as disclosed in Japanese Patent Laid-Open No. 2004-281680, a flange part for placing such an annular member may be provided on the dielectric substrate. In the dielectric substrate, a portion where the wafer such as a silicon wafer to be processed is placed is also referred to as a "first portion" hereinafter. The above-described flange part disposed on the dielectric substrate is also referred to as a "second portion" hereinafter. The second portion (flange part) projects from an outer peripheral end of the first portion further toward an outer peripheral side.

### SUMMARY

To suppress a thermal resistance between the annular member and the second portion, it is preferable that a surface of the second portion is smooth. However, if the entire surface of the second portion is made too smooth, there is a possibility that the annular member is tightly attached to the surface, and the annular member cannot be easily separated.

The present invention has been made in view of such a problem and aims at providing an electrostatic chuck from which an annular member can be easily detached.

To solve the problem described above, the electrostatic chuck according to the present invention includes a first portion including a first placement surface on which an object to be adsorbed is placed, and a second portion projecting from an outer peripheral end of the first portion further toward an outer peripheral side and including a second placement surface on which an annular member is placed. On a part of the second placement surface, a separation promoting part is provided to enable surrounding gas to easily enter a space between itself and the annular member as compared with another portion on the second placement surface.

When the annular member is detached from the second placement surface, surrounding gas smoothly enters the separation promoting part to eliminate a tightly attached state between the second placement surface and the annular member. Due to this, the annular member can be easily detached from the second placement surface.

According to the present invention, it is possible to provide the electrostatic chuck from which the annular member can be easily detached.

### BRIEF DESCRIPTION OF THE DRAWINGS

FIG. 1 is a cross sectional view schematically illustrating a configuration of an electrostatic chuck according to a first embodiment;

FIG. 2 is an expanded view of a configuration of a part of the electrostatic chuck according to the first embodiment;

FIG. 3 is an expanded view of a configuration of a part of an electrostatic chuck according to a modification of the first embodiment; and

FIG. 4 is an expanded view of a configuration of a part of an electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W that is an object to be adsorbed is, for example, a silicon wafer. The electrostatic chuck 10 may be used in an apparatus other than the semiconductor manufacturing apparatus.

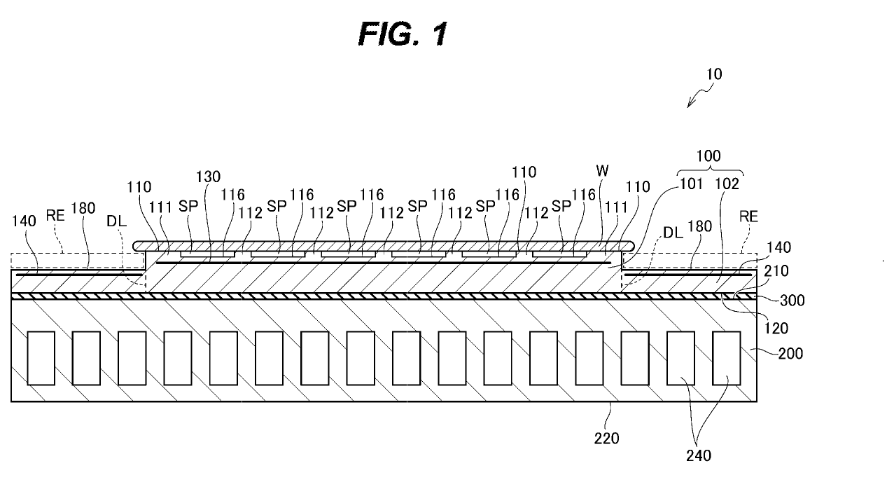

FIG. 1 is a cross sectional view schematically illustrating a configuration of the electrostatic chuck 10 in a state in which the wafer W is adsorbed and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a "placement surface" on which the wafer W is placed. A surface 120 on a lower side in FIG. 1 in the dielectric substrate 100 serves as a "surface to be joined" which is joined to the base plate 200 via a joining layer 300. A perspective in a case where the electrostatic chuck 10 is viewed from the surface 110 side along a direction perpendicular to the surface 110 will also be hereinafter expressed as "top view". The surface 110 corresponds to a "first placement surface" in the present embodiment.

The dielectric substrate 100 includes a first portion 101 and a second portion 102. The first portion 101 is a substantially cylindrical portion extending from the surface 110 toward a lower side in FIG. 1 to the surface 120. It can be said that the first portion 101 is a portion including the surface 110 as the first placement surface in the dielectric substrate 100.

The second portion 102 is an annular portion projecting from an outer peripheral end of the first portion 101 further toward an outer peripheral side, and is a portion also called a "flange part" of the dielectric substrate 100. In FIG. 1, a boundary between the first portion 101 and the second portion 102 is indicated by a dotted line DL. The second portion 102 is thinner than the first portion 101. That is, a dimension of the second portion 102 in a direction perpendicular to the surface 110 (in FIG. 1, an upper and lower direction) is smaller than a dimension of the first portion 101 in the same direction. The surface 120 described above is a surface on a lowermost side of the first portion 101 in FIG. 1, and is also a surface on the lowermost side of the second portion 102. A surface 180 on an uppermost side of the second portion 102 is present at a position lower than the surface 110 in FIG. 1.

When a process on the wafer W is to be performed in the semiconductor manufacturing apparatus, an annular member RE that is called a focus ring and the like is arranged around the wafer W. The surface 180 of the second portion 102 serves as a "placement surface" on which the annular member RE is placed. The surface 180 is a surface parallel to the surface 110. The whole annular member RE may be supported by the surface 180 from a lower side as in the example of FIG. 1, or only a part of the annular member RE may be supported thereby. The surface 180 corresponds to a "second placement surface" in the present embodiment. It can be said that the second portion 102 is a portion including the surface 180 as the second placement surface in the dielectric substrate 100.

An adsorption electrode 130 is provided inside the first portion 101 in the dielectric substrate 100. The adsorption electrode 130 is a thin planar layer made of a metallic material such as, for example, tungsten, and is arranged so as to be parallel to the surface 110. As a material of the adsorption electrode 130, molybdenum, platinum, palladium, and the like may be used in addition to tungsten. When a voltage is applied to the adsorption electrode 130 from an outside via a feed line which is not illustrated in the drawing, an electrostatic force is generated between the surface 110 and the wafer W, and according to this, the wafer W is adsorbed and held. As a configuration of the above-described feed line, various configurations in related art can be adopted. The single adsorption electrode 130 may be provided as so-called a "monopolar" electrode as in the present embodiment, but may also include two adsorption electrodes as so-called "bipolar" electrodes.

An internal electrode 140 is provided inside the second portion 102 in the dielectric substrate 100. The internal electrode 140 is a thin planar layer formed of the same material as that of the adsorption electrode 130, and is arranged so as to be parallel to the surface 180. When a voltage is applied to the internal electrode 140 from the outside via the feed line which is not illustrated in the drawing, an electrostatic force is generated between the surface 180 and the annular member RE, and according to this, the annular member RE is adsorbed and held. As a configuration of the above-described feed line connected to the internal electrode 140, various configurations in related art can be adopted. The single internal electrode 140 may be provided as so-called a "monopolar" electrode as in the present embodiment, but may also include two adsorption electrodes as so-called "bipolar" electrodes.

Inside the dielectric substrate 100, an RF electrode for generating plasma to be adsorbed to the wafer W side may be provided in addition to the above-described adsorption electrode 130 and internal electrode 140. The adsorption electrode 130 and the internal electrode 140 may also be used as the above-described RF electrode.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. In the base plate 200, a surface 210 on the upper side in FIG. 1 serves as a "surface to be joined" which is joined to the dielectric substrate 100 via the joining layer 300. An outer shape of the surface 210 in top view is substantially the same as an outer shape of the second portion 102 in top view.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase an insulation withstand (breakdown) voltage of the base plate 200.

A coolant flow path 240 through which a coolant flows is formed inside the base plate 200. When the process such as etching is performed in the semiconductor manufacturing apparatus, the coolant is supplied from the outside to the coolant flow path 240, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 240 are performed via openings which are not illustrated in the drawing and which are formed in a surface 220 opposite to the surface 210 in the base plate 200. The coolant flow path 240 is formed so as to pass through not only a range overlapped with the first portion 101 in top view but also a range overlapped with the second portion 102. Due to this, not only the wafer W but also the annular member RE is cooled by the coolant passing through the coolant flow path 240.

When a process on the wafer W is performed in the semiconductor manufacturing apparatus, the annular member RE is placed on the surface 180 as described above. When the process on the wafer W is completed, the annular member RE is detached from the surface 180. At this point, if the entire surface 180 becomes a smooth surface, there is a possibility that the annular member RE is tightly attached to the surface 180, and the annular member RE cannot be easily separated therefrom. Thus, in the electrostatic chuck according to the present embodiment, the configuration of the surface 180 is devised to prevent the above-described phenomenon from being caused.

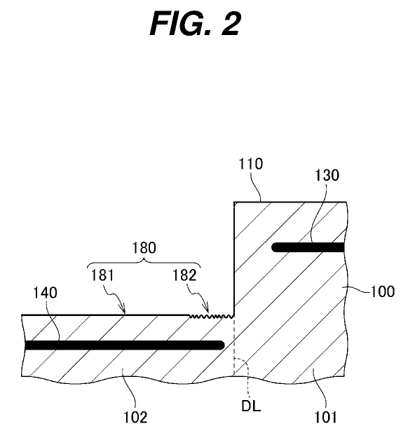

FIG. 2 schematically illustrates configurations of a boundary part (that is, the dotted line DL) between the first portion 101 and the second portion 102 and portions in the vicinity thereof in the electrostatic chuck 10 in FIG. 1. As illustrated in FIG. 2, a surface shape of the surface 180 is not uniform as a whole. The surface 180 includes a smooth part 181 and a roughened surface part 182.

The smooth part 181 is a portion of the surface 180 excluding the roughened surface part 182 described below. The smooth part 181 is formed as a smooth surface as a whole. When the entire smooth part 181 is tightly attached to the annular member RE, a thermal resistance between the annular member RE and the second portion 102 is reduced. As a result, the annular member RE can be efficiently cooled.

The roughened surface part 182 is a portion in a vicinity of an end part on an inner peripheral side of the surface 180, and is a portion adjacent to the above-described smooth part 181. Surface roughness (for example, Ra) of the roughened surface part 182 is larger than surface roughness of the smooth part 181. The roughened surface part 182 extends in an annular shape so as to surround the first portion 101 on the outer peripheral side in top view. The entire roughened surface part 182 is not necessarily continuous in the annular shape in top view, and may be partially interrupted. It can be said that the roughened surface part 182 as described above is a portion where the surface roughness is locally roughened at a part of the surface 180.

At the roughened surface part 182, a gap between the surface 180 and the annular member RE is slightly larger than that at the smooth part 181, so that surrounding gas (for example, air) can easily enter the gap. Due to this, when the annular member RE is to be detached from the surface 180, the surrounding gas smoothly enters a space right above the roughened surface part 182, and the tightly attached state between the surface 180 and the annular member RE is immediately eliminated. Accordingly, the annular member RE can be easily detached from the surface 180. The roughened surface part 182 is a portion where the surrounding gas can easily enter a space between itself and the annular member RE as compared with the other portion (that is, the smooth part 181) of the surface 180, and corresponds to a "separation promoting part" in the present embodiment.

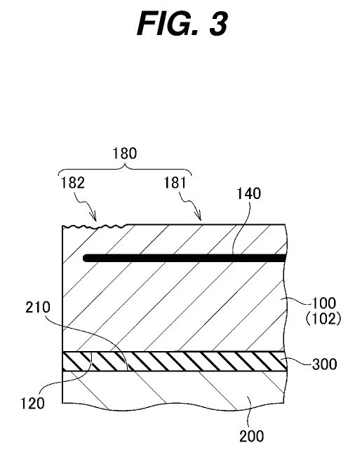

The roughened surface part 182 can be provided at an optional position on the surface 180. However, a portion in the vicinity of the end part on the inner peripheral side of the surface 180 is a portion where the surrounding gas enters first when the annular member RE is to be detached. Thus, as in the present embodiment, the roughened surface part 182 is preferably provided at the portion in the vicinity of the end part on the inner peripheral side of the surface 180. For the same reason, as in a modification illustrated in FIG. 3, the roughened surface part 182 may be provided at a portion in the vicinity of an end part on the outer peripheral side of the surface 180.

A second embodiment will be described. In the following, features different from those of the first embodiment will be mainly described, and description of features common to those of the first embodiment is omitted as appropriate.

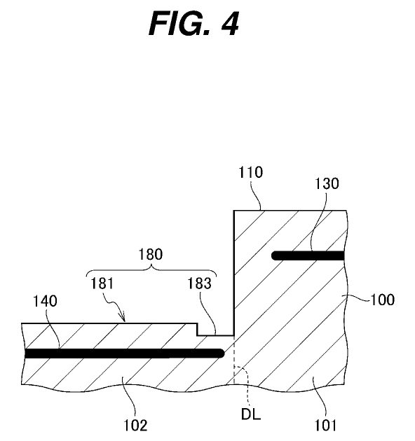

FIG. 4 schematically illustrates, similarly to FIG. 2, configurations of the boundary part (that is, the dotted line DL) between the first portion 101 and the second portion 102 and the portions in the vicinity thereof in the electrostatic chuck 10 according to the present embodiment. The surface 180 in the present embodiment includes the smooth part 181 and a groove part 183.

The smooth part 181 is a portion formed as a smooth surface as a whole. A range in which the smooth part 181 is provided and a surface shape of the smooth part 181 are the same as those in the first embodiment.

The groove part 183 is a portion in the vicinity of the end part on the inner peripheral side of the surface 180, and is a portion adjacent to the above-described smooth part 181. At the groove part 183, the surface 180 is retreated in a recessed shape toward the surface 120 side (the lower side in FIG. 4). The groove part 183 is a groove extending in the annular shape so as to surround the first portion 101 on the outer peripheral side in top view. The entire groove part 183 is not necessarily continuous in the annular shape in top view, and may be partially interrupted. It can be said that the groove part 183 as described above is a portion where a part of the surface 180 is retreated in the recessed shape.

At the groove part 183, a gap between the surface 180 and the annular member RE is larger than that at the smooth part 181, so that the surrounding gas (for example, air) can easily enter the gap. Due to this, when the annular member RE is to be detached from the surface 180, the surrounding gas smoothly enters an inner side of the groove part 183, and the tightly attached state between the surface 180 and the annular member RE is immediately eliminated. Accordingly, the annular member RE can be easily detached from the surface 180. The groove part 183 is a portion where the surrounding gas can easily enter a space between itself and the annular member RE as compared with the other portion (that is, the smooth part 181) of the surface 180, and corresponds to the "separation promoting part" in the present embodiment.

The groove part 183 can also be provided at an optional position on the surface 180. However, a portion of the surface 180 in the vicinity of the end part on the inner peripheral side is a portion where the surrounding gas enters first when the annular member RE is to be detached. Thus, as in the present embodiment, the groove part 183 is preferably provided at the portion in the vicinity of the end part on the inner peripheral side of the surface 180. For the same reason, the groove part 183 may be provided at a portion in the vicinity of the end part on the outer peripheral side of the surface 180.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a first portion including a first placement surface on which an object to be adsorbed is placed; and
a second portion projecting from an outer peripheral end of the first portion further toward an outer peripheral side, and including a second placement surface on which an annular member is placed,
wherein a separation promoting part is provided at a part of the second placement surface to enable surrounding gas to easily enter a space between the separation promoting part and the annular member as compared with another portion on the second placement surface.

2. The electrostatic chuck according to claim 1, wherein the separation promoting part is a portion in a vicinity of an end part on an inner peripheral side of the second placement surface, or a portion in a vicinity of an end part on an outer peripheral side of the second placement surface.

3. The electrostatic chuck according to claim 2, wherein the separation promoting part is a portion where a part of the second placement surface is retreated in a recessed shape.

4. The electrostatic chuck according to claim 2, wherein the separation promoting part is a portion where surface roughness is locally roughened at a part of the second placement surface.
